(19) United States
(12) Patent Application Publication
(10) Pub. No.: US 2025/0250671 A1
(43) Pub. Date: Aug. 7, 2025

(54) NON-CARBONYL METAL DEPOSITION ADJUVANT, DEPOSITION METHOD OF LATE TRANSITION METAL IN CHANNEL HOLE USING THE SAME, AND SEMICONDUCTOR DEVICE

(71) Applicant: Samsung Electronics Co., Ltd., Suwon-si (KR)

(72) Inventors: Seung-Min RYU, Suwon-si (KR); Daeun KIM, Suwon-si (KR); Hyunwoo KIM, Suwon-si (KR); Younjoung CHO, Suwon-si (KR)

(73) Assignee: Samsung Electronics Co., Ltd., Suwon-si (KR)

(21) Appl. No.: 19/012,072

(22) Filed: Jan. 7, 2025

(30) Foreign Application Priority Data
Feb. 1, 2024 (KR) 10-2024-0016203
Sep. 13, 2024 (KR) 10-2024-0126134
Dec. 19, 2024 (KR) 10-2024-0191026

(51) Int. Cl. C23C 16/455; C23C 16/18; C23C 16/56; H10B 12/00; H10B 41/35; H10B 43/35

(52) U.S. Cl. CPC C23C 16/45534; C23C 16/18; C23C 16/45553; C23C 16/56; H10B 12/05; H10B 41/35; H10B 43/35

(57) ABSTRACT

A non-carbonyl metal deposition adjuvant may include at least one of Si, O, S, or N. A deposition method may include feeding the non-carbonyl metal deposition adjuvant to a channel hole where amorphous Si is deposited before feeding a late transition metal precursor into the channel hole where the amorphous Si is deposited. A semiconductor device may include a semiconductor structure defining the channel hole, where the semiconductor structure may include a metal layer including crystallized Si and a late transition metal and where the semiconductor structure may include a thin film surrounding the channel hole. The thin film may include oxide films and nitride films alternately disposed. Grains in the metal layer may include the crystallized silicon. The late transition metal may have an average diameter of greater than or equal to 50 nm.

### CROSS-REFERENCE TO RELATED APPLICATION

This application claims priority to and the benefit of Korean Patent Application No. 10-2024-0016203 filed in the Korean Intellectual Property Office on Feb. 1, 2024, Korean Patent Application No. 10-2024-0126134 filed in the Korean Intellectual Property Office on Sep. 13, 2024, and Korean Patent Application No. 10-2024-0191026 filed in the Korean Intellectual Property Office on Dec. 19, 2024, the entire contents of which are incorporated herein by reference.

### BACKGROUND

### (a) Field

This disclosure relates to a non-carbonyl metal deposition adjuvant, a deposition method of late transition metal in channel hole using the same and/or semiconductor device, and more specifically to a method of improving step coverage of an ALD/CVD late transition metal deposition process by first depositing the non-carbonyl metal deposition adjuvant, before depositing a late transition metal precursor into the channel hole where another material (e.g., amorphous silicon) is deposited.

### (b) Description of the Related Art

Due to improved integration of memory and non-memory semiconductor devices, the microstructure of substrates may be becoming more complex day by day.

For example, a width and a depth of the microstructure may be increased to greater than or equal to about 20:1 or greater than or equal to about 100:1 (hereinafter, referred to be an “aspect ratio”). However, as the aspect ratio of the microstructure becomes larger, forming stacked layers with a uniform thickness along the complex microstructure surface may be more difficult.

Accordingly, step coverage may be important. Step coverage may define a thickness ratio of the stacked layers formed at the top and bottom of the microstructure in a depth direction. When step coverage remains at a level of about 90%, it may be more difficult to develop electrical characteristics of the devices, etc. Step coverage of 100% means that the stacked layers at the top and bottom of the microstructure have the same thickness. It may be necessary to develop technology for securing step coverage as close to 100% as possible.

Thin films for a semiconductor device may be nitride layers, oxide layers, metal layers, etc. The nitride layers may mainly contain semi-metals (metalloids), non-metals, late transition metals, etc. The oxide layers may mainly contain semi-metals (metalloids), transition metals, or the like. The metal layers may mainly contain late transition metals, transition metals, or etc.

The thin films generally may be used as a diffusion barrier between a doped silicon layer of the semiconductor and an interlayer wiring material such as aluminum (Al), copper (Cu), etc. However, when a tungsten (W) thin film is deposited on a substrate, the thin films may be used as an adhesion layer.

On the other hand, as seen earlier, because high step coverage of the thin films may be needed to secure desired uniformity and properties of the thin films deposited on the substrate, an ALD (atomic layer deposition) process utilizing a surface reaction rather than a CVD (chemical vapor deposition) process utilizing a vapor reaction may be used. However, the ALD process still may have problems realizing high step coverage (e.g., 100% step coverage).

### SUMMARY

One aspect of the present disclosure provides a non-carbonyl-based metal deposition adjuvant that can improve a step coverage of a late transition metal deposition process, such as Ni, a method of depositing a late transition metal in a channel hole using the same, and/or a semiconductor device. Additionally, one aspect of the present disclosure is not limited to VNAND (Vertical NAND), but can also be applied to 3D DRAM.

According to an embodiments, a non-carbonyl metal deposition adjuvant according may include at least one of Si, O, S, or N.

A method for depositing a late transition metal in a channel hole according to one aspect of some example embodiments may include feeding a non-carbonyl metal deposition adjuvant to a channel hole where amorphous Si is deposited, the non-carbonyl metal deposition adjuvant including at least one of Si, O, S, or N; and feeding a late transition metal precursor into the channel hole where the amorphous Si is deposited. The feeding the non-carbonyl metal deposition adjuvant may be performed before the feeding of the late transition metal precursor.

In some embodiments, the non-carbonyl metal deposition adjuvant may include Si and may be represented by any one of Chemical Formula 1-1 to Chemical Formula 1-3.

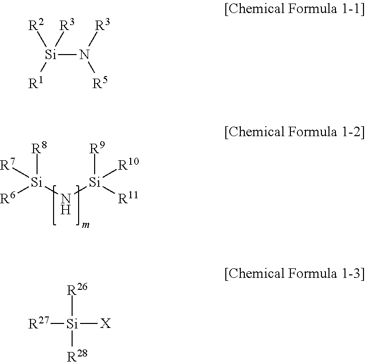

In Chemical Formula 1-1 to Chemical Formula 1-3,
R¹ to R³ and R⁶ to R¹¹ each independently may be hydrogen, a halogen, or a substituted or unsubstituted C1 to C20 alkyl group,
R⁴ and R⁵ each independently may be a hydrogen atom or a substituted or unsubstituted C1 to C20 alkyl group,
R²⁶ to R²⁸ each independently may be a substituted or unsubstituted C1 to C20 alkyl group,
X may be a halogen atom, and
m may be an integer of 0 or 1.

In some embodiments, the non-carbonyl metal deposition adjuvant may include O and may be represented by any one of Chemical Formula 2-1 to Chemical Formula 2-3.

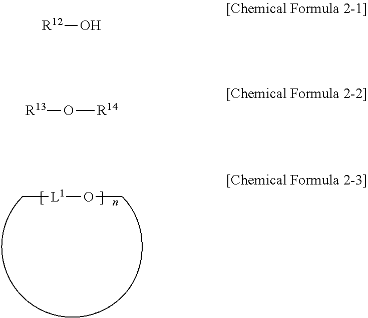

In Chemical Formula 2-1 to Chemical Formula 2-3,
R¹² to R¹⁴ each independently may be a substituted or unsubstituted C1 to C20 alkyl group,
L¹ may be a substituted or unsubstituted C1 to C20 alkylene group, and n may be an integer of 2 or more (e.g., 2 to 10).

In some embodiments, the non-carbonyl metal deposition adjuvant including S may be a thiol-based compound, a sulfide-based compound, a disulfide-based compound, or a thiophene-based compound.

In some embodiments, the non-carbonyl metal deposition adjuvant may include S and may be represented by any one of Chemical Formula 3-1 to Chemical Formula 3-4.

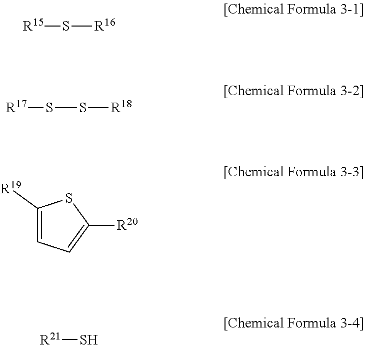

In Chemical Formula 3-1 to Chemical Formula 3-4,
R¹⁵ to R²¹ each independently may be a substituted or unsubstituted C1 to C20 alkyl group.

In some embodiments, the non-carbonyl metal deposition adjuvant may include N and may be represented by any one of Chemical Formula 4-1, Chemical Formula 4-2, and a nitrogen-containing heterocycle.

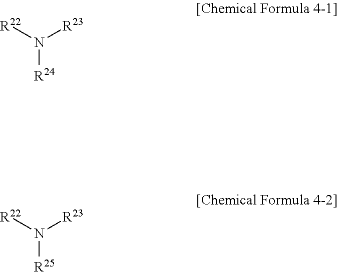

In Chemical Formula 4-1 and Chemical Formula 4-2,
R²² to R²⁴ each independently may be a hydrogen atom or a substituted or unsubstituted C1 to C20 alkyl group, and
R²⁵ may be a substituted or unsubstituted C6 to C20 aryl group.

In some embodiments, the non-carbonyl metal deposition adjuvant may be represented by any one of Chemical Formula A to Chemical Formula N.

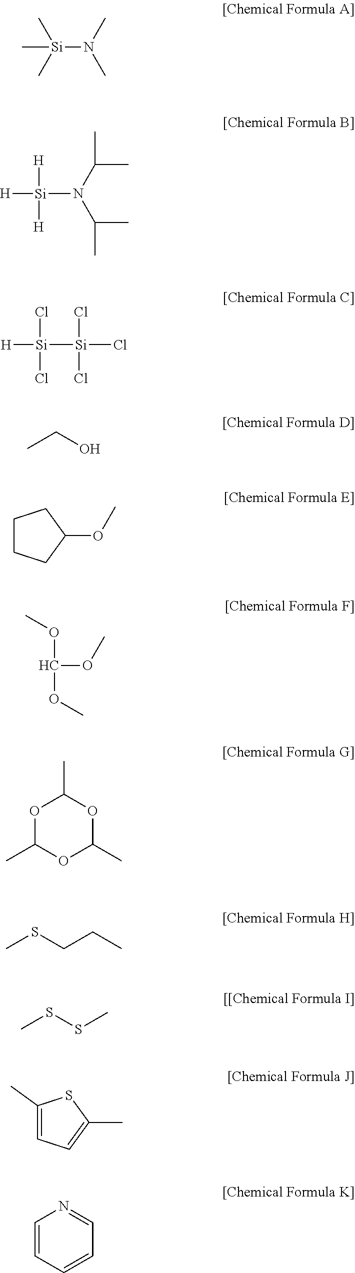

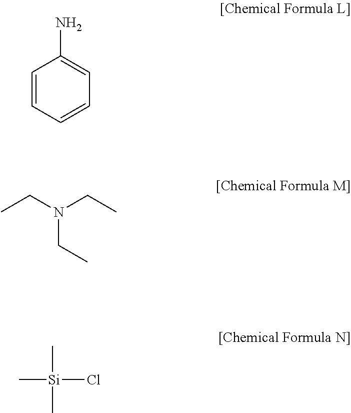

In some embodiments, the non-carbonyl-based metal deposition adjuvant may be a non-ester-based metal deposition adjuvant.

In some embodiments, the deposition method of late transition metal in channel hole may further include, after the feeding the late transition metal precursor into the channel hole where the amorphous Si is deposited, crystallizing amorphous Si in the channel hole by metal induced crystallization (MIC).

In some embodiments, the crystallizing amorphous Si in the channel hole may be performed by an annealing process.

In some embodiments, the annealing process may be performed by a laser annealing process.

In some embodiments, the late transition metal precursor may include at least one of a Co precursor, a Ni precursor, a Cu precursor, a Rh precursor, a Pd precursor, an Ag precursor, an Ir precursor, a Pt precursor, or an Au precursor.

In some embodiments, the late transition metal precursor may include the Ni precursor, and the Ni precursor may be represented by any one selected from Group 1.

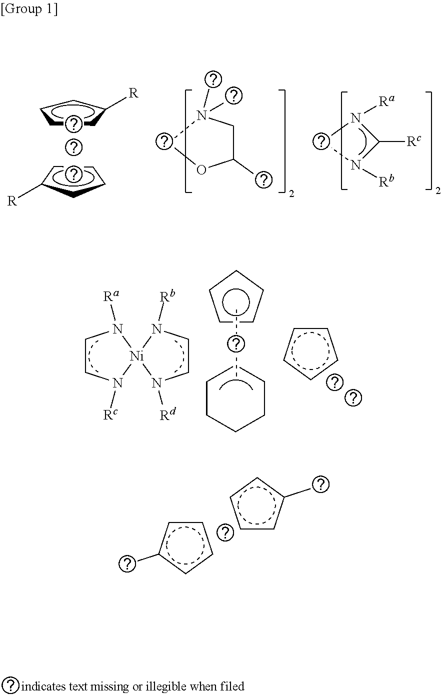

In Group 1,
R and R^{a} to R^{d} each independently may be a hydrogen atom or a substituted or unsubstituted C1 to C20 alkyl group.

In some embodiments, the Ni precursor may be any one of the compounds listed in Table 1, but is not necessarily limited thereto.

TABLE 1

| Ni precursor | Structural Formulas |
|---|---|
| 1 | 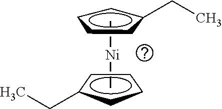 |
| 2 | 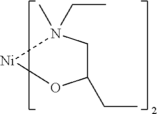 |
| 3 | 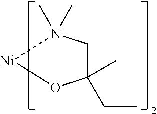 |
| 4 | 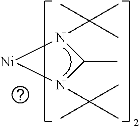 |
| 5 | 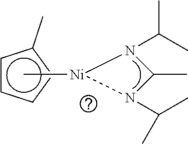 |
| 6 | 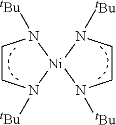 |
| 7 | 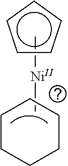 |
| 8 | 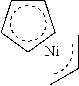 |
| 9 | 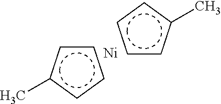 |
| 10 | 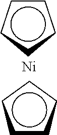 |

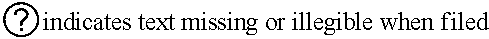

In some embodiments, the late transition metal precursor may include the Co precursor, and the Co precursor may be represented by any one selected from Group 2.

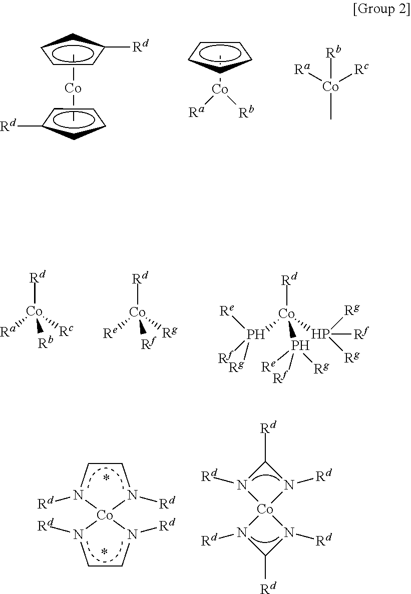

In Group 2,
R is nitrogen oxide,
R^{a} to R^{c} are carbon oxide,
R^{d} may be a hydrogen atom or a substituted or unsubstituted C1 to C20 alkyl group, and
R^{e} to R^{f} each independently may be a substituted or unsubstituted C1 to C20 alkyl group or a substituted or unsubstituted C1 to C20 alkoxy group.

The Co precursor may be any one of the compounds listed in Table 2, but is not necessarily limited thereto.

TABLE 2

| Co precursor | Structural Formulas |
|---|---|
| 1 | 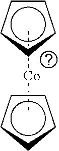 |
| 2 | 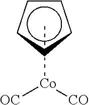 |
| 3 | 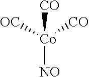 |
| 4 | 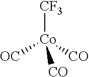 |
| 5 | 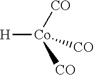 |
| 6 | 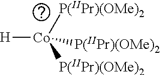 |
| 7 | 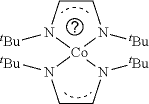 |
| 8 | 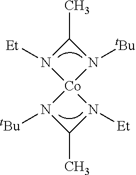 |
| 9 | 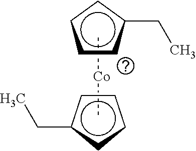 |

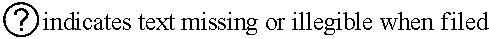

In some embodiments, the late transition metal precursor may include the Ni precursor, and the Cu precursor may be a Cu-containing heterocycle.

In some embodiments, the Cu precursor may be any one of the compounds listed in Table 3, but is not necessarily limited thereto.

TABLE 3

| Cu precursor | Structural Formulas |
|---|---|
| 1 | 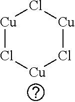 |
| 2 | 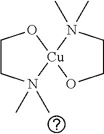 |
| 3 | 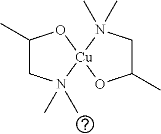 |
| 4 | 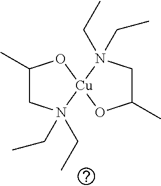 |
| 5 | 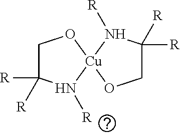 |
| | (R and R′ each independently may be a substituted or |
| | unsubstituted C1 to C20 alkyl group) |
| 6 | 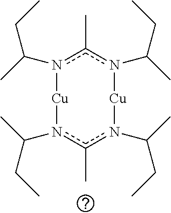 |
| 7 | 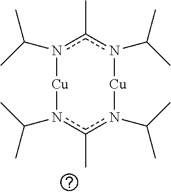 |
| 8 | 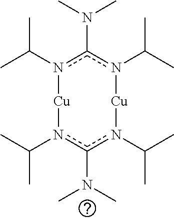 |
| 9 | 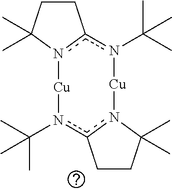 |
| 10 | 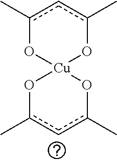 |
| 11 | 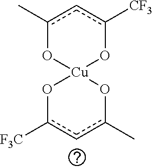 |
| 12 | 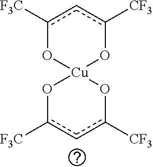 |
| 13 | 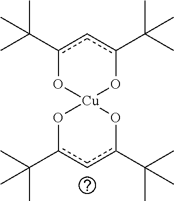 |
| 14 | 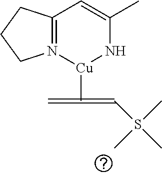 |
| 15 | 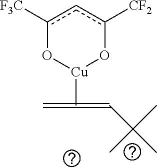 |
| 16 | 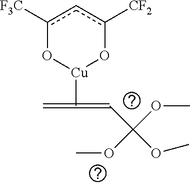 |
| 17 | 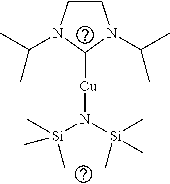 |
| 18 | 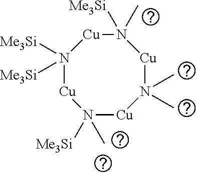 |

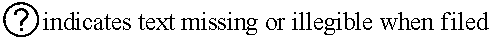

In some embodiments, the channel hole may have a depth of about 10 μm to about 35 μm.

According to some example embodiments, a semiconductor device may include a semiconductor structure defining a channel hole. The semiconductor structure may include a metal layer including crystallized Si and a late transition metal. The semiconductor structure may include a thin film surrounding the channel hole. The thin film may include oxide films and nitride films alternately disposed, and grains in the metal layer including the crystallized silicon and the late transition metal have an average diameter of greater than or equal to about 50 nm.

In some embodiments, the semiconductor device may include VNAND (Vertical NAND) or 3D DRAM.

By first injecting and depositing a metal deposition adjuvant that can occupy the reaction adsorption site of the late transition metal precursor into the channel hole where amorphous silicon is deposited, the adsorption of the late transition metal precursor can be controlled, thereby improving process step coverage (step coating properties or step rate).

### BRIEF DESCRIPTION OF THE DRAWINGS

FIG. 1 is a diagram showing that NiSi is formed only in the upper portion of the channel hole in which amorphous silicon is deposited by injecting a Ni precursor without injecting a metal deposition adjuvant, and thus the amorphous Si remains without crystallization even after annealing.

FIG. 2 is a diagram showing that when only the Ni precursor is added without a metal deposition adjuvant, the Ni precursor is not adsorbed to the bottom of the channel hole, making uniform crystallization of the channel hole impossible even after annealing.

FIG. 3 is a diagram showing the process order of a method of first injecting a metal deposition adjuvant into a channel hole where amorphous silicon is deposited, then adding a Ni precursor to form NiSi, and then heat treating to crystallize the amorphous Si.

FIG. 4 is a diagram showing that when a metal deposition adjuvant is first injected and then a Ni precursor is injected, the Ni precursor is uniformly adsorbed to the bottom of the channel hole, enabling uniform crystallization of the channel hole.

### DETAILED DESCRIPTION OF THE EMBODIMENTS

Expressions such as “at least one of,” when preceding a list of elements, modify the entire list of elements and do not modify the individual elements of the list. For example, “at least one of A, B, or C,” and similar language (e.g., “at least one selected from the group consisting of A, B, and C” and “at least one of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes. When ranges are specified, the range includes all values therebetween such as increments of 0.1%.

While the term “equal to” is used in the description of some example embodiments, it should be understood that some imprecisions may exist. Thus, when one element is referred to as “equal to” another element, it should be understood that an element or a value may be “equal to” another element within a desired manufacturing or operational tolerance range (e.g., +10%).

Inventive concepts will be described more fully hereinafter with reference to the accompanying drawings, in which some embodiments of inventive concepts are shown. As those skilled in the art would realize, the described embodiments may be modified in various different ways, all without departing from the spirit or scope of inventive concepts.

The drawings and description are to be regarded as illustrative in nature and not restrictive. Like reference numerals designate like elements throughout the specification.

The size and thickness of each constituent element as shown in the drawings are randomly indicated for better understanding and ease of description, and this disclosure is not necessarily limited to as shown. In the drawings, the thickness of layers, films, panels, regions, etc., are exaggerated for clarity. In addition, in the drawings, for better understanding and ease of description, the thickness of some layers and areas is exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. The word “on” or “above” means being disposed on or below the object portion, and does not necessarily mean being disposed on the upper side of the object portion based on a gravitational direction.

In addition, unless explicitly described to the contrary, the word “comprise,” and variations such as “comprises” or “comprising,” will be understood to imply the inclusion of stated elements but not the exclusion of any other elements.

In addition, throughout the specification, when referring to “plane,” it means when the target part is viewed from above, and when referring to “cross section,” it means when viewing the cross section of the target portion vertically cut from the side.

The present disclosure provides technology of more uniformly (conformally) depositing a metal layer by first injecting a metal deposition adjuvant with a novel structure, which may be an inhibitor capable of occupying an adsorption site before injecting a late transition metal precursor in a late transition metal deposition process during the semiconductor process and in addition, controlling a deposition rate and step coverage.

As semiconductors become miniaturized, demand may increase for semiconductors with higher speed and/or lower power consumption. A silicide process is being considered for a contact material of source/drain or forming a gate electrode of metal oxide semiconductors. Among silicides, nickel silicide (NiSi) is a material recently drawing lots of attention due to lower silicon consumption and lower resistance. In addition, a low-resistance Ni film may be used as an electrode for DRAM capacitors and also considered as a multi-wiring material for semiconductors.

A widely used method of forming NiSi may include forming a nickel (Ni) film on an Si substrate or a poly Si substrate in a PVD method such as sputtering.

Because the PVD method for depositing the Ni film may have undesirable and/or poorer step coverage in a high aspect ratio structure, a CVD process has been adopted to improve the step coverage.

However, in the conventional CVD method, as further miniaturization of semiconductor devices brings about a more complex three-dimensional structure, it may be difficult to control uniform deposition and a deposition rate. The present inventors have achieved the uniform deposition of a precursor through pre-deposition of a metal deposition adjuvant capable of occupying an active site before injecting the precursor.

In the conventional CVD method or GPD (Gas Phase Deposition) method, because it may be difficult to secure step coverage and control a metal deposition amount in the 3D structure with a high aspect ratio. In order to realize finer deposition, the metal deposition adjuvant with a novel structure, which plays a role of limiting and/or preventing concentration of the late transition metal at the top of a channel hole as an inhibitor, and the deposition method of first injecting the metal deposition adjuvant has been invented.

A conventional deposition process of a metal, specifically, the late transition metal proceeds with injecting (feeding) the late transition metal precursor and simultaneously or sequentially injecting a reducing agent.

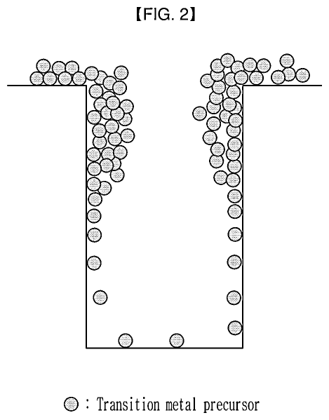

When the late transition metal precursor is injected into the channel hole deposited with amorphous silicon, there may be a problem due to a reaction between the channel hole deposited with the amorphous silicon and the late transition metal precursor. The late transition metal precursor may be deposited more at the top of the channel hole compared to the bottom of the channel hole; consequently, the late transition metal precursor may not be uniformly deposited (refer to FIG. 2)

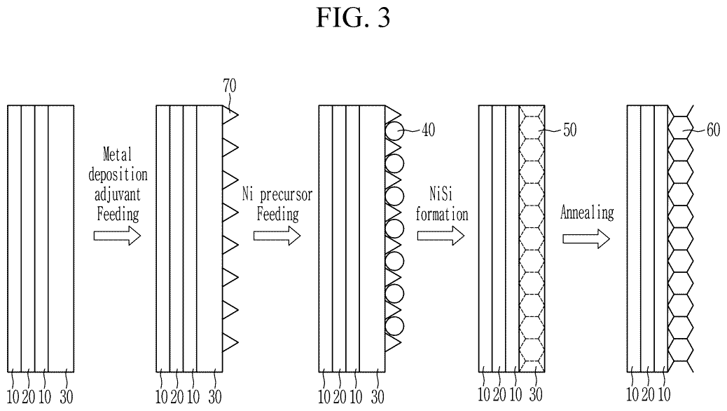

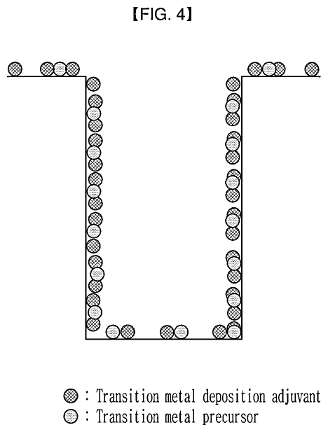

However, in some example embodiments, a non-carbonyl metal deposition adjuvant including Si, O, S, and/or N, which is the metal deposition adjuvant according to some example embodiments, may be deposited in the channel hole 30 on the amorphous silicon before the injecting the late transition metal precursor (refer to FIG. 3). The metal deposition adjuvant may be more intensively deposited at an active site where the late transition metal precursor is supposed to be deposited; consequently, the late transition metal precursor subsequently injected thereinto may not be deposited on the active site and may move deeper into the bottom of the channel hole. As a result, the late transition metal precursor may be more uniformly deposited from the top of the channel hole to the bottom thereof (refer to FIG. 4). In other words, the metal deposition adjuvant according to some example embodiments may contribute to forming a more uniform metal layer. Furthermore, in some example embodiments, a deposition rate may be improved and/or an injection amount of the metal precursor may be limited and/or minimized.

On the other hand, the metal deposition adjuvant according to one aspect of some example embodiments must be a non-carbonyl-based compound. If the metal deposition adjuvant includes Si, O, S, and/or N, but is a carbonyl-based compound, the late transition metal precursor may not deposit smoothly on the active site and/or the metal deposition adjuvant may not contribute to forming a more uniform metal film.

In some example embodiments, the non-carbonyl-based compound refers to a compound not including a carbonyl group (*—C(═O)—*) in the compound structure. For example, the non-carbonyl-based compound according to one aspect of embodiments refers to a non-ester-based metal deposition adjuvant, that is, a compound not including an ester group (*—C(═O)O—* or *—OC(═O)—*) in the compound structure. In other words, the metal deposition adjuvant according to one aspect may be a compound including Si, O, S, and/or N in the compound structure and simultaneously, not including a carbonyl group and specifically, not including an ester group. For example, because the structure represented by *—OC(═O)O—* also includes a carbonyl group or an ester group, a compound including the structure represented by *—OC(═O)O—* may not be the metal deposition adjuvant according to one aspect of some example embodiments.

For example, the non-carbonyl metal deposition adjuvant including Si may be represented by any one of Chemical Formula 1-1 to Chemical Formula 1-3, but is not necessarily limited thereto.

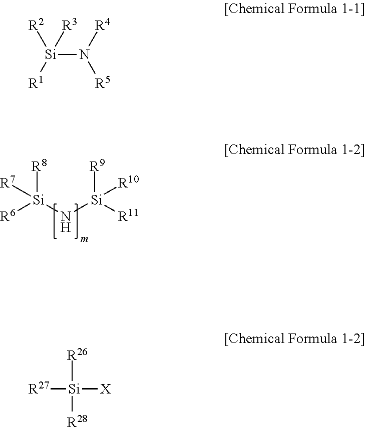

In Chemical Formula 1-1 to Chemical Formula 1-3,
R¹ to R³ and R⁶ to R¹¹ each independently may be hydrogen, a halogen, or a substituted or unsubstituted C1 to C20 alkyl group,
R⁴ and R⁵ each independently may be a hydrogen atom or a substituted or unsubstituted C1 to C20 alkyl group,
R²⁶ to R²⁸ each independently may be a substituted or unsubstituted C1 to C20 alkyl group,
X may be a halogen atom, and
m may be an integer of 0 or 1.

For example, the non-carbonyl metal deposition adjuvant including Si may be represented by any one of Chemical Formula A to Chemical Formula C and Chemical Formula N, but is not necessarily limited thereto.

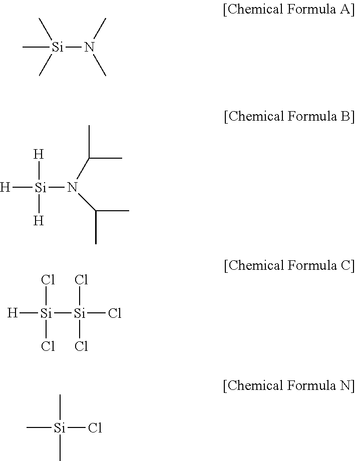

For example, non-carbonyl metal deposition adjuvant including O may be represented by any one of Chemical Formula 2-1 to Chemical Formula 2-3, but is not necessarily limited thereto.

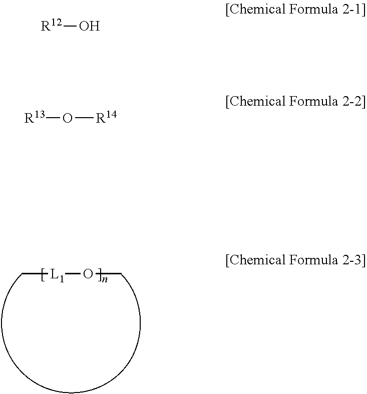

In Chemical Formula 2-1 to Chemical Formula 2-3,
R¹² to R¹⁴ each independently may be a substituted or unsubstituted C1 to C20 alkyl group,
L¹ may be a substituted or unsubstituted C1 to C20 alkylene group, and
n may be an integer of 2 or more.

Specifically, the substituted or unsubstituted C1 to C20 alkyl group refers to a linear structure and does not include a cyclic structure such as a cycloalkyl group.

For example, the non-carbonyl metal deposition adjuvant including O may be represented by any one of Chemical Formula D to Chemical Formula G, but is not necessarily limited thereto.

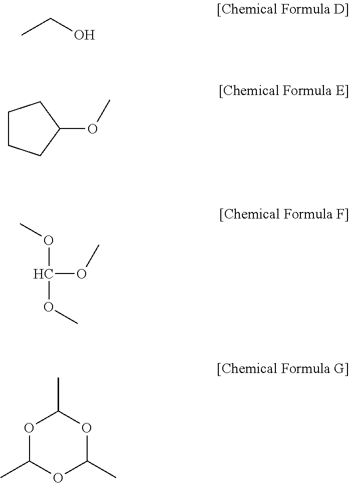

For example, the non-carbonyl metal deposition adjuvant including S may be a thiol-based compound, a sulfide-based compound, a disulfide-based compound, or a thiophene-based compound, and may specifically be represented by any one of Chemical Formula 3-1 to Chemical Formula 3-4, but is not necessarily limited thereto.

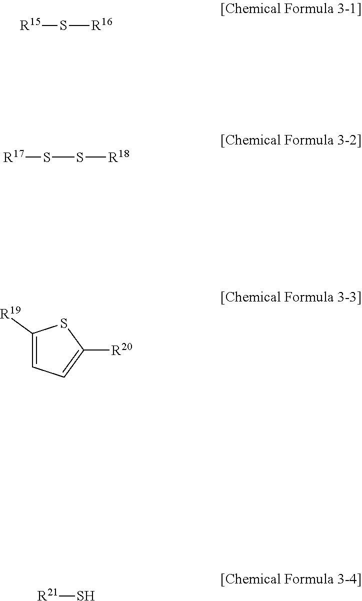

In Chemical Formula 3-1 to Chemical Formula 3-4,
R¹⁵ to R²¹ each independently may be a substituted or unsubstituted C1 to C20 alkyl group.

For example, the non-carbonyl metal deposition adjuvant including S may be represented by any one of Chemical Formula H to Chemical Formula J, but is not necessarily limited thereto.

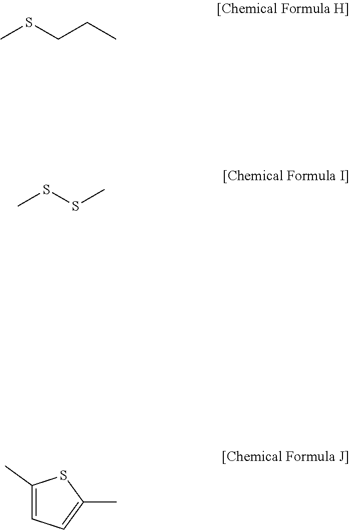

For example, non-carbonyl metal deposition adjuvant including N

Chemical may be represented by any one of Chemical Formula 4-1, Chemical Formula 4-2, and a nitrogen-containing heterocycle, but is not necessarily limited thereto.

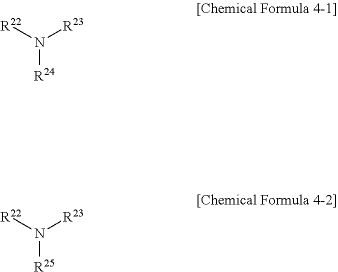

In Chemical Formula 4-1 and Chemical Formula 4-2,
R²² to R²⁴ each independently may be a hydrogen atom or a substituted or unsubstituted C1 to C20 alkyl group, and
R²⁵ may be a substituted or unsubstituted C6 to C20 aryl group.

For example, the non-carbonyl metal deposition adjuvant including N may be represented by any one of Chemical Formula K to Chemical Formula M, but is not necessarily limited thereto.

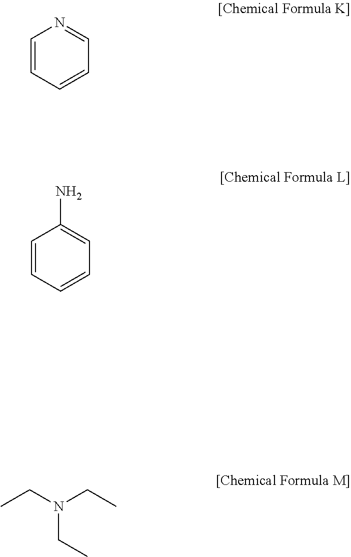

The non-carbonyl metal deposition adjuvant according to one aspect of some example embodiments may be a compound with purity of about 99.9% or more, a compound with purity of about 99.95% or more, or a compound with purity of about 99.99% or more. For reference, if a compound with purity of less than about 99%, because impurities may remain in a thin film, or a side reaction with a precursor or a reactant may occur, it is recommended to use a material with purity of about 99% or more, if possible.

The non-carbonyl metal deposition adjuvant may be used preferably in the atomic layer deposition (ALD) process or the chemical vapor deposition (CVD) process, wherein the non-carbonyl metal deposition adjuvant may not interfere with adsorption of the late transition metal precursor compound but work as a late transition metal deposition adjuvant which contributes to a uniform reaction of amorphous silicon deposited in the channel hole with the late transition metal at the top and the bottom inside the channel hole on and thus formation of NiSi. Ultimately, through the subsequent process, a metal induced crystallization (MIC) process and an annealing process, grains with a large size of about 50 nm or more (e.g., 50 nm to 100 nm, 50 nm to 500 nm, but not limited thereto) may be observed both at the top and bottom inside the channel hole.

In order to improve performance of VNAND or 3D DRAM, size growth of poly grains in the channel hole is essential, wherein the non-carbonyl metal deposition adjuvant according to one aspect of some example embodiments may be first injected before injecting the late transition metal to secure great size growth of the poly grains in the channel hole to about 50 nm or more. As aforementioned, as semiconductor devices become smaller, because there may be an increasing demand for developing reliable electrode materials, which minimizes an increase in specific resistance, the smaller size of the poly grains in the channel hole, the larger resistivity, wherein the size growth of the poly grains in the channel hole may reduce the resistivity, resultantly improving reliability of the semiconductor devices.

The size of the poly grains in the channel hole is increased by more than two times through the metal induced crystallization (MIC) process and the annealing process after forming NiSi, wherein the poly grain size may be about 50 nm to about 150 nm. When the poly grain size in the channel hole is less than about 50 nm, the resistivity is so large as to deteriorate the reliability of semiconductor devices, but considering a width and the like of the channel hole, the poly grain size in the channel hole may not be greater than about 150 nm. If the poly grain size in the channel hole is greater than about 150 nm, semiconductor devices having such a channel hole may not go well with a current miniaturization trend of the semiconductor devices which are increasingly smaller.

A deposition method of late transition metal in channel hole according to another aspect includes feeding a non-carbonyl metal deposition adjuvant including Si, O, S, and/or N to a channel hole where amorphous Si is deposited; and feeding a late transition metal precursor, wherein the feeding of the non-carbonyl metal deposition adjuvant is performed before the feeding of the late transition metal precursor.

The non-carbonyl-based metal deposition adjuvant including Si, O, S, and/or N used in the deposition method of late transition metal in channel hole is the same as described above.

The deposition method of late transition metal in channel hole is slightly different from the existing deposition method in its order. Specifically, in that the non-carbonyl-based metal deposition adjuvant, which may be an inhibitor capable of occupying the active site, is first injected before injecting the late transition metal precursor, the deposition method of late transition metal in channel hole according to one aspect of some example embodiments is differentiated from conventional deposition methods. Next, the late transition metal precursor and reactant are injected. At this time, the precursor and two or more reactants (NH₃, N₂, hydrazine, etc.) may be sprayed (injected) simultaneously or sequentially.

For example, a deposition method of late transition metal in channel hole according to one aspect of some example embodiments may further include feeding (injecting) the late transition metal precursor and then crystallizing amorphous Si in the channel hole by metal induced crystallization (MIC).

The metal induced crystallization is performed in order to crystallize the amorphous Si and increase the poly grain size in the channel hole, as aforementioned, because the late transition metal precursor is injected after first injecting the non-carbonyl metal deposition adjuvant, the metal induced crystallization may be performed in a state that the late transition metal precursor is uniformly deposited in the channel hole, ultimately realizing crystallization of all amorphous Si in the channel hole, that is, from the top to bottom of the channel hole and an increase in its grain size. For the crystallization of amorphous Si, the late transition metal such as Ni and the like should be supplied, wherein in the conventional deposition method, because the late transition metal precursor is directly injected without injecting the non-carbonyl metal deposition adjuvant and thus not supplied to the bottom of the channel hole, the amorphous Si is not crystallized at the bottom of the channel hole even by the metal-induced crystallization but remains still as amorphous. In addition, because the top of the channel hole may be crystallized, while the bottom of the channel hole is not crystallized, it is not possible to expect uniform size growth of poly grains over the top and bottom of the channel hole.

For example, the deposition method of late transition metal in channel hole according to one aspect of some example embodiments may further include crystallizing amorphous Si in the channel hole and then annealing.

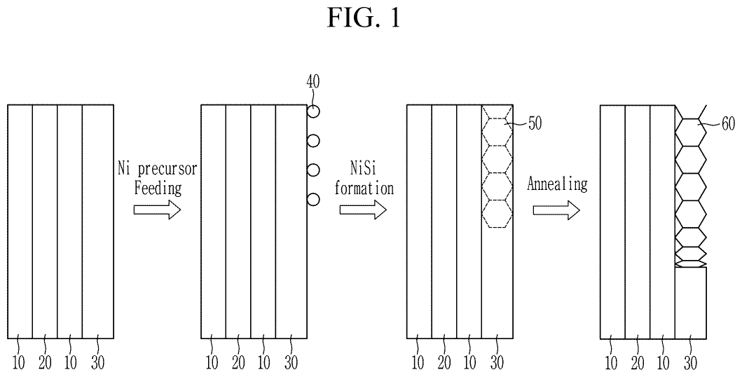

Referring to FIGS. 1 and 3, a stacked structure may include first layers 10 and second layers 20 alternately arranged on a side of a amorphous Si structure 30 filling a channel hole 30. The first layers 10 and second layers 20 may be different materials (e.g., silicon oxide and silicon nitride, but not limited thereto). A Ni precursor 40 may be deposited on the amorphous Si structure 30 in the channel hole and processed (e.g., heated) to form a nickel silicide (NiSi) 50. Then, amorphous Si structure 30 may be at least partially crystallized into crystallized silicon 60 by an annealing process.

As shown in FIG. 1, NiSi 50 is formed only in the upper portion of the channel hole in which amorphous silicon 30 is deposited by injecting a Ni precursor 40 without injecting a metal deposition adjuvant, and thus the amorphous Si 30 remains without crystallization even after annealing. In FIG. 1, only part of the amorphous Si structure 30 is crystalized to provide crystalized silicon 60.

As shown in FIG. 1, NiSi 50 is formed only in the upper portion of the channel hole in which amorphous silicon 30 is deposited by injecting a Ni precursor 40 without injecting a metal deposition adjuvant, and thus the amorphous Si 30 remains without crystallization even after annealing. In FIG. 1, only part of the amorphous Si structure 30 is crystalized to provide crystalized silicon 60.

It is confirmed that through the high temperature annealing process, crystallization 60 of the channel hole 30 and specifically, the channel hole 30 deposited with amorphous Si is achieved by NiSi 50, metal silicide.

The channel hole 30 may be crystallized by NiSi 50, metal silicide, in the metal induced crystallization (MIC) method, wherein the crystallization may proceed from the top of the channel hole 30 to the bottom thereof. Accordingly, the channel hole 30 may have a single crystal structure or a single crystal-like structure.

The annealing process may be performed at about 800° C. or more, for example, about 800° C. to about 1000° C. The annealing process is performed as a rapid thermal process (RTP) or a laser annealing process for a relatively short time, for example, for about 10 seconds to about 3 minutes. The annealing process may be performed as a batch type which is performed on multiple wafers, for example, a plate layer or as a single type which is performed on one wafer.

While FIGS. 1 and 3 illustrate examples where a Ni precursor is used to form a nickel silicide, some example embodiments are not limited thereto. The late transition metal precursor may include a Co precursor, a Ni precursor, a Cu precursor, a Rh precursor, a Pd precursor, an Ag precursor, an Ir precursor, a Pt precursor, an Au precursor, or a combination thereof

The Ni precursor may be represented by any one selected from Group 1. The Co precursor may be represented by any one selected from Group 2, and the Cu precursor may be a Cu-containing heterocycle. The specific type of the late transition metal precursor is not necessarily limited thereto, but when using the following types of late transition metal precursor, it is possible to more effectively achieve more uniform growth of the poly grain size in the channel hole along with the metal deposition adjuvant according to one aspect of some example embodiments.

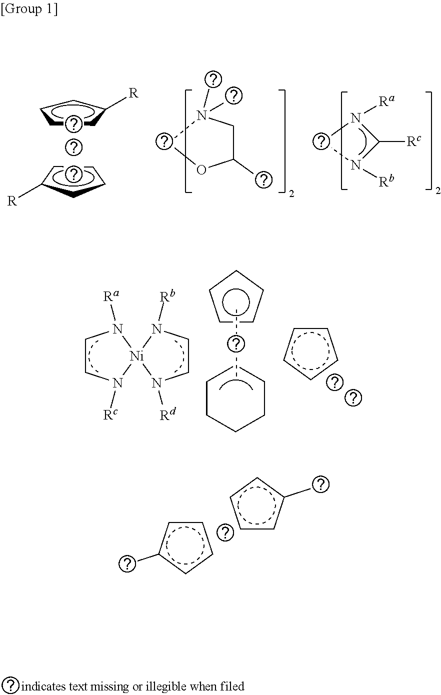

In Group 1,
R and R^{a} to R^{d} each independently may be a hydrogen atom or a substituted or unsubstituted C1 to C20 alkyl group.

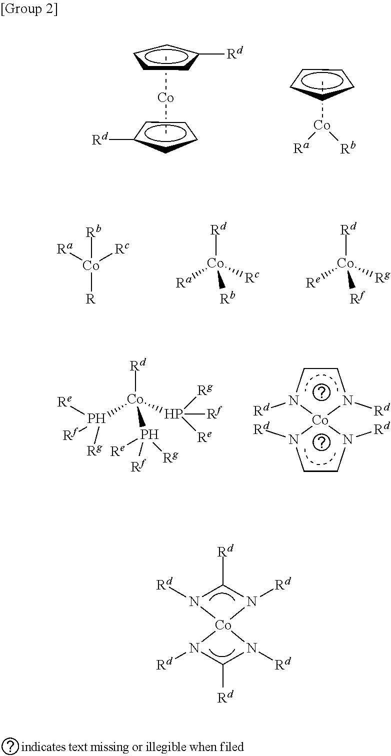

In Group 2,
R is nitrogen oxide,
R^{a} to R^{c} are carbon oxide,
R^{d} may be a hydrogen atom or a substituted or unsubstituted C1 to C20 alkyl group, and
R^{e} to R^{f} each independently may be a substituted or unsubstituted C1 to C20 alkyl group or a substituted or unsubstituted C1 to C20 alkoxy group.

For example, the Cu-containing heterocycle may be a heterocycle located between any two atoms selected from a halogen atom, an oxygen atom, and a nitrogen atom. For example, the heterocycle may include a spiro compound.

For example, the Ni precursor may be any one of the compounds listed in Table 1, the Co precursor may be any one of the compounds listed in Table 2, and the Cu precursor may be any one of the compounds listed in Table 3, but are not necessarily limited thereto.

TABLE 1

| Ni precursor | Structural Formulas |
|---|---|
| 1 | 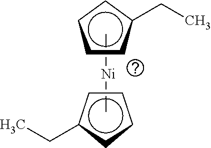 |
| 2 | 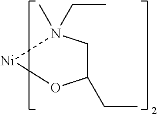 |
| 3 | 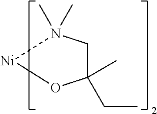 |
| 4 | 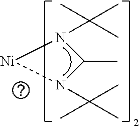 |
| 5 | 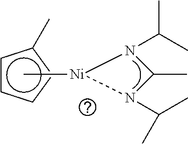 |
| 6 | 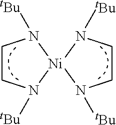 |
| 7 | 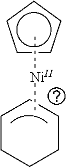 |
| 8 | 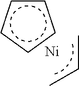 |
| 9 | 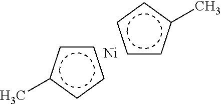 |
| 10 | 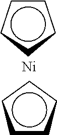 |

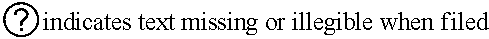

TABLE 2

| Co precursor | Structural Formulas |
|---|---|
| 1 | 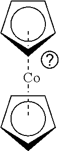 |
| 2 | 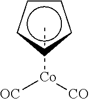 |
| 3 | 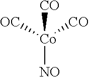 |
| 4 | 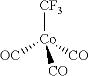 |
| 5 | 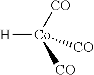 |
| 6 | 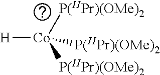 |
| 7 | 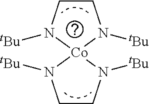 |
| 8 | 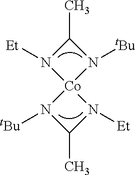 |
| 9 | 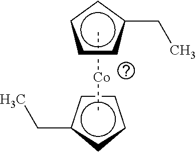 |

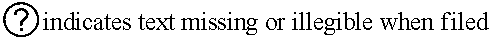

TABLE 3

| Cu precursor | Structural Formulas |
|---|---|
| 1 | 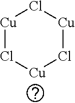 |
| 2 | 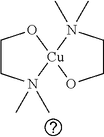 |
| 3 | 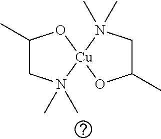 |
| 4 | 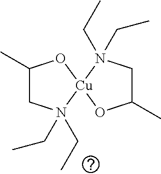 |
| 5 | 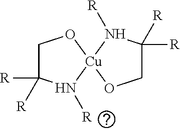 |
| | (R and R′ each independently may be a substituted or |
| | unsubstituted C1 to C20 alkyl group) |
| 6 | 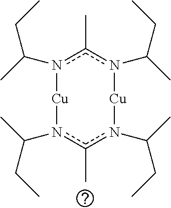 |
| 7 | 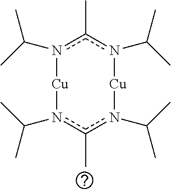 |
| 8 | 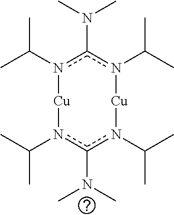 |
| 9 | 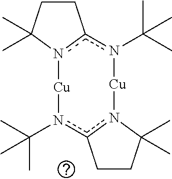 |
| 10 | 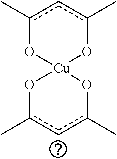 |
| 11 | 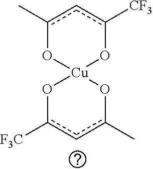 |
| 12 | 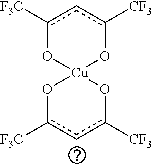 |
| 13 | 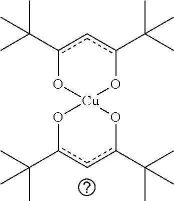 |
| 14 | 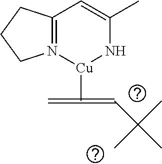 |
| 15 | 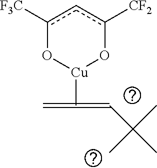 |
| 16 | 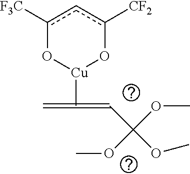 |
| 17 | 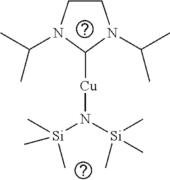 |
| 18 | 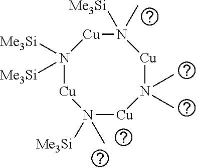 |

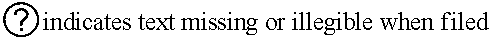

For example, it may be desirable to exclude hafnium (Hf) precursors and titanium (Ti) precursors as the late transition metal precursors when considering compatibility with the non-carbonyl-based metal deposition adjuvant according to one aspect of some example embodiments.

A semiconductor device according to another aspect of some example embodiments may include a semiconductor structure defining a channel hole, wherein the semiconductor structure may include a metal layer including crystallized Si and a late transition metal, wherein the semiconductor structure may include a thin film surrounding the channel hole, and wherein the thin film may include oxide films and nitride films alternately disposed, and grains in the metal layer including the crystallized silicon and the late transition metal may have an average diameter of greater than or equal to about 50 nm.

For example, the grains in the metal layer including the crystallized silicon and late transition metal may have an average diameter of about 50 nm to about 150 nm.

For example, the channel hole may have a depth of about 10 μm to about 35 μm.

For example, the semiconductor device may include Vertical NAND (VNAND) or 3D DRAM.

Although some example embodiments have been described above, inventive concepts are not limited to the above-described example embodiments, and various additions, omissions, substitutions, and changes may be made. Additionally, it is possible to form other embodiments by combining elements from different embodiments.

Hereinafter, various experiments conducted to evaluate grain size and resistivity using a metal deposition adjuvant according to an embodiment will be described. The experiments described below do not limit the present disclosure.

### EXAMPLES

A device including a channel hole and a thin film (where the oxide layer and the nitride layer were alternated) surrounding the channel hole was manufactured by depositing a WC mask on a mold in which an oxide layer and a nitride layer were alternately stacked and etching a channel hole to a depth of 30 μm at less than 0° C., and amorphous Si was deposited in the channel hole. Subsequently, an ALD deposition process was performed inside the channel hole by using components shown in Tables 4-1 and 4-2. Its specific process sequence is as follows.
1. Injecting of metal deposition adjuvant
2. Purging of metal deposition adjuvant
3. Injecting of late transition metal precursor and reactivity gas (NH₃)
4. Purging of late transition metal precursor and reactivity gas (NH₃)

TABLE 4-1

| | Examples | | | | | | | |
|---|---|---|---|---|---|---|---|---|
| | 1 | 2 | 3 | 4 | 5 | 6 | 7 | 8 |
| Metal | Chemical | Chemical | Chemical | Chemical | Chemical | Chemical | Chemical | Chemical |
| deposition | Formula | Formula | Formula | Formula | Formula | Formula | Formula | Formula |
| adjuvant | A | B | C | D | E | F | G | H |

| | |
|---|---|
| Late transition metal precursor | 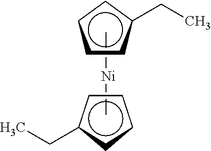 |

TABLE 4-2

| | | | | | | | Comparative | |
|---|---|---|---|---|---|---|---|---|
| | Examples | | | | | | Examples | |
| | 9 | 10 | 11 | 12 | 13 | 14 | 1 | 2 |
| Metal | Chemical | Chemical | Chemical | Chemical | Chemical | Chemical | Chemical | Chemical |
| deposition | Formula | Formula | Formula | Formula | Formula | Formula | Formula | Formula |
| adjuvant | I | J | K | L | M | N | O | P |

| | |
|---|---|
| Late transition metal precursor | 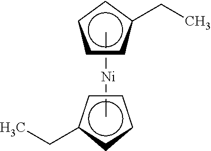 |

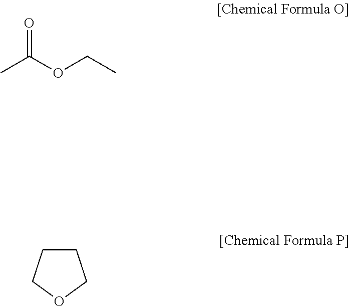

### Comparative Example 3

A device was manufactured in the same manner as in Example 1 except that the injecting and purging processes of the metal deposition adjuvant were omitted.

### (Evaluation)

The devices according to Examples 1 to 14 and Comparative Examples 1 to 3 were evaluated with respect to an average size of poly grains and resistivity of each channel hole, and the results are shown in Tables 5-1 and 5-2. The resistivity evaluation was performed by using a 4-point probe system (CMT-SR2000N, Advanced Instrument Technologies Inc.). The average size of poly grains means an average size of all grains observed from the top to the bottom of each channel hole.

TABLE 5-1

| | Examples | | | | | | | |
|---|---|---|---|---|---|---|---|---|
| | 1 | 2 | 3 | 4 | 5 | 6 | 7 | 8 |
| Grain | 149 | 145 | 147 | 52 | 55 | 54 | 57 | 138 |
| size | | | | | | | | |
| (nm) | | | | | | | | |
| Resistivity | 21 | 24 | 23 | 105 | 103 | 105 | 101 | 30 |
| (μΩ · cm) | | | | | | | | |

TABLE 5-2

| | | | | | | | Comparative | | |
|---|---|---|---|---|---|---|---|---|---|
| | Examples | | | | | | Examples | | |
| | 9 | 10 | 11 | 12 | 13 | 14 | 1 | 2 | 3 |
| Grain | 133 | 132 | 125 | 124 | 121 | 45 | 31 | 40 | 19 |
| size | | | | | | | | | |
| (nm) | | | | | | | | | |
| Resis- | 35 | 36 | 42 | 43 | 45 | 107 | 109 | 108 | 115 |
| tivity | | | | | | | | | |
| (μΩ · | | | | | | | | | |
| cm) | | | | | | | | | |

As shown in Tables 5-1 and 5-2, if the metal deposition adjuvant was injected before injecting the late transition metal precursor, an increase in grain size and a decrease in resistivity occurred, and in addition, the grain size and the resistivity were confirmed to be controlled depending on types of the metal deposition adjuvant.

Accordingly, in a conventional ALD process method of injecting an Ni precursor to form Ni or NiSi, it was difficult to uniformly deposit in a 3D structure, but in embodiments of inventive concepts, improving step coverage of the deposition process may be expected by using the metal deposition adjuvant with a specific structure.

While some embodiments of inventive concepts have been described, it is to be understood that inventive concepts are not limited to the disclosed embodiments, but, on the contrary, are intended to cover various modifications and equivalent arrangements included within the spirit and scope of the appended claims.

What is claimed is:

1. A non-carbonyl metal deposition adjuvant comprising:
at least one of Si, O, S, or N.

2. The non-carbonyl metal deposition adjuvant of claim 1, wherein
the non-carbonyl metal deposition adjuvant includes Si and is represented by any one of Chemical Formula 1-1 to Chemical Formula 1-3: 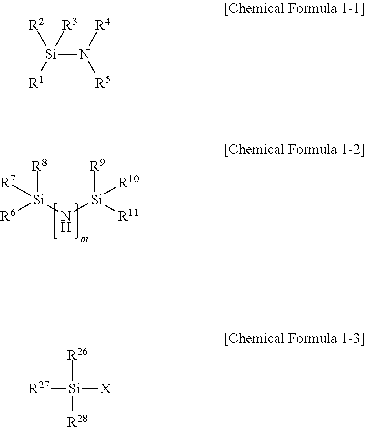
wherein, in Chemical Formula 1-1 to Chemical Formula 1-3,
R¹ to R³ and R⁶ to R¹¹ are each independently hydrogen, a halogen, or a substituted or unsubstituted C1 to C20 alkyl group,
R⁴ and R⁵ are each independently a hydrogen atom or a substituted or unsubstituted C1 to C20 alkyl group,
R²⁶ to R²⁸ are each independently a substituted or unsubstituted C1 to C20 alkyl group,
X is a halogen atom, and
m is an integer of 0 or 1.

3. The non-carbonyl metal deposition adjuvant of claim 1, wherein
the non-carbonyl metal deposition adjuvant includes O and is represented by any one of Chemical Formula 2-1 to Chemical Formula 2-3: 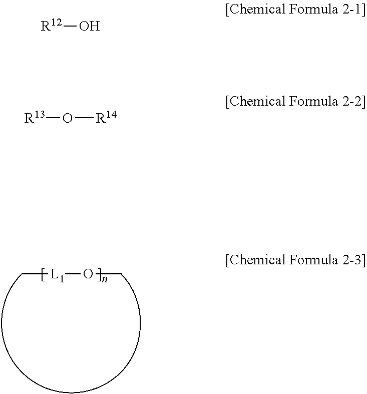
wherein, in Chemical Formula 2-1 to Chemical Formula 2-3,
R¹² to R¹⁴ are each independently a substituted or unsubstituted C1 to C20 alkyl group,
L¹ is a substituted or unsubstituted C1 to C20 alkylene group, and
n is an integer of 2 or more.

4. The non-carbonyl metal deposition adjuvant of claim 1, wherein
the non-carbonyl metal deposition adjuvant includes S and is a thiol-based compound, a sulfide-based compound, a disulfide-based compound, or a thiophene-based compound.

5. The non-carbonyl metal deposition adjuvant of claim 1, wherein
the non-carbonyl metal deposition adjuvant includes S and is represented by any one of Chemical Formula 3-1 to Chemical Formula 3-4: 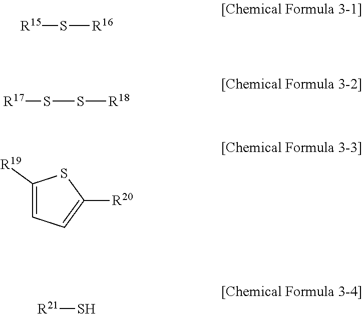
wherein, in Chemical Formula 3-1 to Chemical Formula 3-4,
R¹⁵ to R²¹ are each independently a substituted or unsubstituted C1 to C20 alkyl group.

6. The non-carbonyl metal deposition adjuvant of claim 1, wherein
the non-carbonyl metal deposition adjuvant includes N and is represented by any one of Chemical Formula 4-1, Chemical Formula 4-2, and a nitrogen-containing heterocycle: 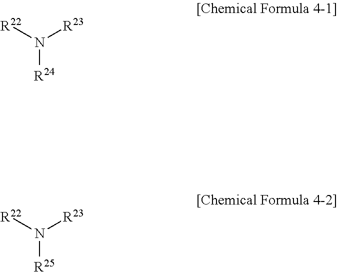
wherein, in Chemical Formula 4-1 and Chemical Formula 4-2,
R²² to R²⁴ are each independently a hydrogen atom or a substituted or unsubstituted C1 to C20 alkyl group, and
R²⁵ is a substituted or unsubstituted C6 to C20 aryl group.

7. The non-carbonyl metal deposition adjuvant of claim 1, wherein
the non-carbonyl metal deposition adjuvant includes Si, N, or both Si and N, and
the non-carbonyl metal deposition adjuvant is represented by any one of Chemical Formula A to Chemical Formula C, Chemical Formula K to Chemical Formula M, and Chemical Formula N:

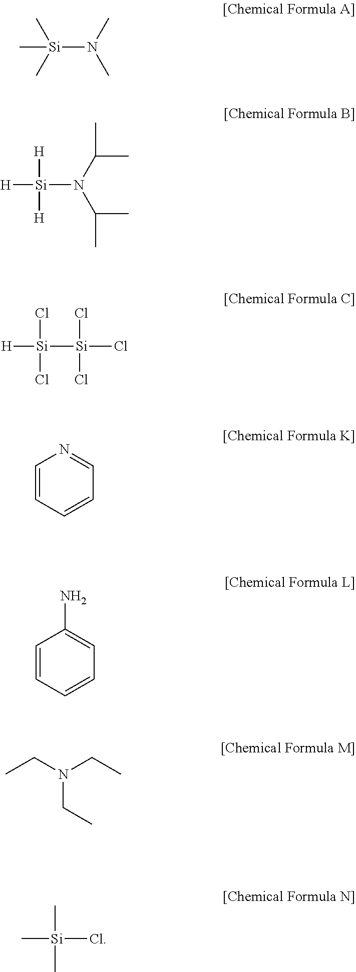

8. The non-carbonyl metal deposition adjuvant of claim 1, wherein
the non-carbonyl metal deposition adjuvant includes O and is represented by any one of Chemical Formula D to Chemical Formula G:

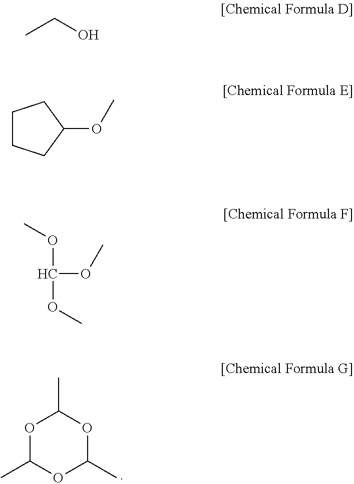

9. The non-carbonyl metal deposition adjuvant of claim 1, wherein
the non-carbonyl metal deposition adjuvant includes S and is represented by any one of Chemical Formula H to Chemical Formula J:

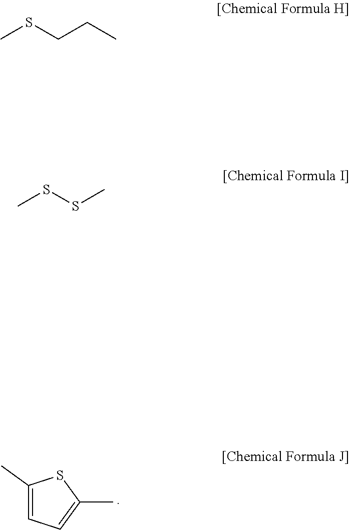

10. The non-carbonyl metal deposition adjuvant of claim 1, wherein
the non-carbonyl metal deposition adjuvant is a non-ester-based metal deposition adjuvant.

11. A deposition method of late transition metal in channel hole, comprising
feeding a non-carbonyl metal deposition adjuvant to a channel hole where amorphous Si is deposited, the non-carbonyl metal deposition adjuvant including at least one of Si, O, S, or N; and
feeding a late transition metal precursor into the channel hole where the amorphous Si is deposited,
wherein the feeding the non-carbonyl metal deposition adjuvant is performed before the feeding the late transition metal precursor.

12. The deposition method of claim 11, further comprising:
after the feeding the late transition metal precursor into the channel hole where the amorphous Si is deposited, crystallizing the amorphous Si in the channel hole by metal induced crystallization (MIC).

13. The deposition method of claim 12, wherein
the crystallizing the amorphous Si in the channel hole is performed by an annealing process.

14. The deposition method of claim 13, wherein
the annealing process includes a laser annealing process.

15. The deposition method of claim 11, wherein
the late transition metal precursor includes at least one of a Co precursor, a Ni precursor, a Cu precursor, a Rh precursor, a Pd precursor, a Ag precursor, an Ir precursor, a Pt precursor, or an Au precursor.

16. The deposition method of claim 15, wherein
the late transition metal precursor includes the Ni precursor, and
the Ni precursor is represented by any one selected from Group 1: 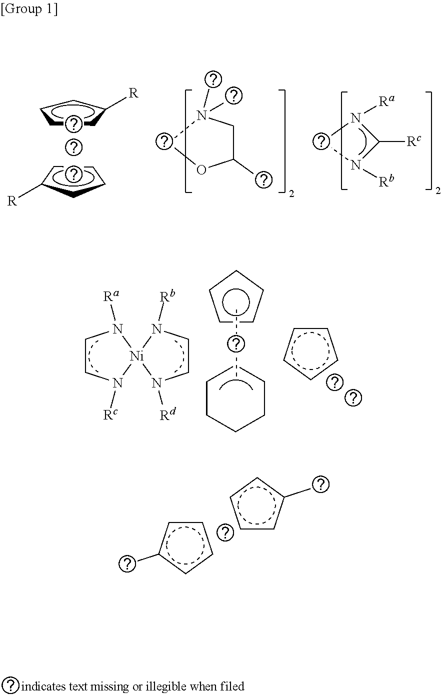
wherein, in Group 1,
R and R^{a} to R^{d} are each independently a hydrogen atom or a substituted or unsubstituted C1 to C20 alkyl group.

17. The deposition method of claim 15, wherein
the late transition metal precursor includes the Co precursor, and
the Co precursor is represented by any one selected from Group 2: 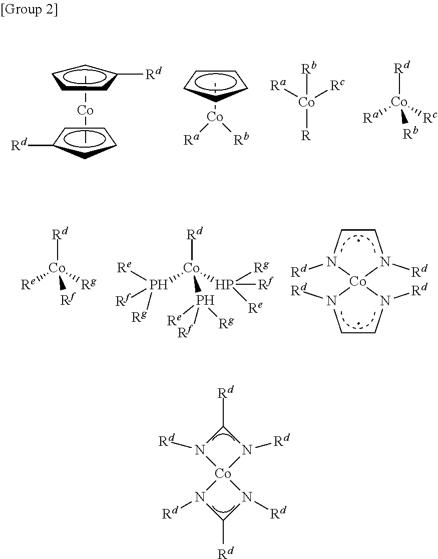
wherein, in Group 2,
R is nitrogen oxide,
R^{a} to R^{c} are carbon oxide,
R^{d} is a hydrogen atom or a substituted or unsubstituted C1 to C20 alkyl group, and
R^{e} to R^{f} are each independently a substituted or unsubstituted C1 to C20 alkyl group or a substituted or unsubstituted C1 to C20 alkoxy group.

18. The deposition method of claim 15, wherein
the late transition metal precursor includes the Cu precursor, and
the Cu precursor is a Cu-containing heterocycle.

19. A semiconductor device, comprising
a semiconductor structure defining a channel hole, the semiconductor structure including a metal layer including crystallized Si and a late transition metal, the semiconductor structure including a thin film surrounding the channel hole, wherein
the thin film includes oxide films and nitride films alternately disposed, and
grains in the metal layer including the crystallized silicon and the late transition metal have an average diameter of greater than or equal to 50 nm.

20. The semiconductor device of claim 19, wherein
the semiconductor device includes VNAND (Vertical NAND) or 3D DRAM.
